(19) United States
(12) Patent Application Publication
(10) Pub. No.: US 2019/0198733 A1
(43) Pub. Date: Jun. 27, 2019

(54) LIGHT EMITTING DEVICE AND MANUFACTURING METHOD THEREOF

(71) Applicant: STANLEY ELECTRIC CO., LTD., Tokyo (JP)

(72) Inventor: Yusuke YAMASHITA, Tokyo (JP)

(73) Assignee: STANLEY ELECTRIC CO., LTD., Tokyo (JP)

(21) Appl. No.: 16/225,207

(22) Filed: Dec. 19, 2018

(30) Foreign Application Priority Data
Dec. 22, 2017 (JP) 2017-246257

(51) Int. Cl. H01L 33/60; H01L 33/54; H01L 33/56

(52) U.S. Cl. CPC H01L 33/60; H01L 33/56; H01L 33/54

(57) ABSTRACT

To provide a light emitting device with high upward emission efficiency. The light emitting device is manufactured by sequentially performing: a step of disposing a phosphor-containing layer on a top face of a light emitting element that is mounted on a substrate; a step of disposing a frame at a position separated from a lateral face of the phosphor-containing layer, on the substrate; a step of pushing a plate-like elastic body against top faces of the phosphor-containing layer and the frame so as to come into contact therewith, and filling, in a state where a lower face of the elastic body is pushed up by the phosphor-containing layer and the frame, a reflection material having fluidity in an uncured state in surroundings of the light emitting element and the phosphor-containing layer so as to be along the lower face of the elastic body; and a step of curing the reflection material to form a reflection member.

### BACKGROUND OF THE INVENTION

### Field of the Invention

The present invention relates to a compact light emitting device that uses a light emitting element, and a manufacturing method thereof.

### Description of the Related Art

Conventionally, compact and high-luminance light emitting devices that are manufactured with the reduced number of members and the low cost have been desired. A chip size package (CSP) has been known in which a light emitting element of the maximum size relative to the size of a light emitting device is used. For example, such a light emitting device has been known that a phosphor-containing layer is mounted on a top face of a light emitting element, and a resin (white color member) containing a reflection material is filled in the surrounding thereof, thereby preventing the light emitting element to emit light to a lateral side and causing the light emitting element to emit light only in an upward direction.

For example, Patent Literatures 1 to 3 each propose a manufacturing method of a light emitting device in which a reflective white color member is dropped in the surrounding of a light emitting element, and thereafter is cured, thereby filling the white color member.

Patent Literature 4 discloses a light emitting device in which a white color member is dropped in the surrounding of a light emitting element, and a plate-like phosphor-containing layer is thereafter mounted above the light emitting element and the white color member.

Patent Literature 5 discloses a method in FIG. 5 in which a phosphor-containing layer is mounted on a top face of a light emitting element, and a curved metallic mold is pressed against the phosphor-containing layer, thereby filling a white color member in a space between the light emitting element and the phosphor-containing layer, and the metallic mold. This can form the white color member with a top face that is inclined in a concave shape in the surrounding of the phosphor-containing layer, and reflect light emitted from the phosphor-containing layer in the inclined direction to an upward direction, thereby allowing the efficiency of taking light in the upward direction to be improved.

### CITATION LIST

### Patent Literatures

[Patent Literature 1] JP-A-6065135

[Patent Literature 2] JP-A-5744643

[Patent Literature 3] JP-A-5746335

[Patent Literature 4] JP-A-5680472

[Patent Literature 5] JP-A-5730680

### SUMMARY OF THE INVENTION

In the light emitting device that uses a light emitting element, light is desired to be effectively used with the downsized, high-luminance, and low cost optical system. However, the configurations disclosed in the abovementioned Patent Literatures 1 to 4 have such a problem that although the white color member shields lateral light emitting of the light emitting element, light is radially emitted from the top face of the phosphor-containing layer, so that the light spreads above, and the light intensity is lowered at a position separated from the light emitting device.

In the light emitting device as in Patent Literature 5 in which the top face of the white color member is formed in a concave shape with a metallic mold, the entire lateral face of the phosphor-containing layer is covered with the white color member, and light that is intended to be emitted from the lateral face of the phosphor-containing layer is shielded. This disables lateral light emitting of phosphor-containing layer to be used.

Moreover, the method specially as in Patent Literature 5 in which the top face of the white color member is formed in a concave shape with a metallic mold requires the metallic mold that corresponds to a minute light emitting element with about 1 mm squares. Forming such a compact metallic mold in a curved shape is not easy. In addition, a metallic mold is required to be produced for each size of the light emitting element, and the curvatures of a plurality of metallic molds are also required to be uniformed in order to mass-manufacture light emitting devices with high accuracy. In addition, by considering a position shift when the light emitting element is mounted, a metallic mold is required to be formed in a size that corresponds to the shift, so that forming the metallic mold is difficult.

An aspect of the invention is to provide a light emitting device with high upward emission efficiency.

### Solution to Problem

A first aspect of the invention provides a light emitting device as follows. In other words, the light emitting device includes: a substrate; a chip-like light emitting body that is mounted on the substrate; and a reflection member that is filled in a surrounding of the light emitting body. In the light emitting device, a top face of the reflection member is an inclined surface with an edge, on a side of the light emitting body, that is in contact with a lateral face of the light emitting body, and an edge, on a side of an outer circumference, at least a part of which is located at a position higher than a height of the light emitting body, and the inclined surface has a concave-shaped curved surface that is temporarily inclined in a direction to approach the substrate as being apart from the edge on the side of the light emitting body toward the side of the outer circumference, and is thereafter inclined in a direction to be apart from the substrate.

### Advantageous Effects of Invention

The invention can provide the light emitting device with high emission efficiency of light emitted from the light emitting body because a top face of the reflection member is an inclined surface with an edge, on a side of the light emitting body, that is in contact with a lateral face of the light emitting body, and an edge, on a side of an outer circumference, at least a part of which is located at a position higher than a height of the light emitting body, and the inclined surface has a concave-shaped curved surface that is temporarily inclined in a direction to approach the substrate as being apart from the edge on the side of the light emitting body toward the side of the outer circumference, and is thereafter inclined in a direction to be apart from the substrate.

### BRIEF DESCRIPTION OF THE DRAWINGS

FIG. 1A is a top view and FIG. 1B is a cross-sectional view of a light emitting device according to a first embodiment;

FIG. 2 is a cross-sectional view illustrating paths of light emitted from a light emitting element 11 in the first embodiment;

FIGS. 3A to 3D are explanation views illustrating a manufacturing process of the light emitting device in the first embodiment;

FIG. 4A is a top view and FIG. 4B is a cross-sectional view of a light emitting device according to a second embodiment; and

FIG. 5 is a cross-sectional view illustrating paths of light emitted from the light emitting element 11 in the second embodiment.

### DETAILED DESCRIPTION OF THE INVENTION

Hereinafter, a light emitting device according to an embodiment of the invention will be described.

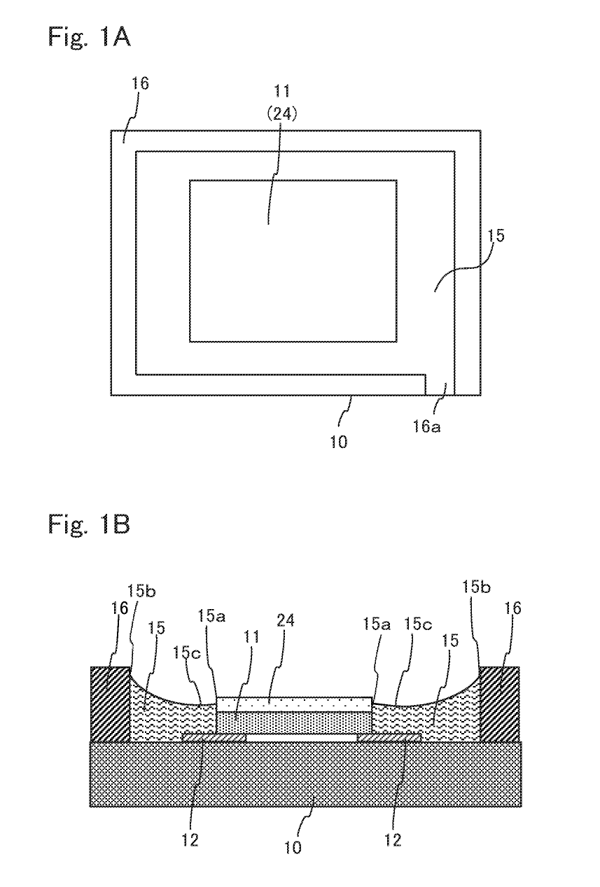

FIGS. 1A and 1B respectively illustrate a top view and a cross-sectional view of a light emitting device according to a first embodiment. In the present embodiment, a reflection material that has fluidity in an uncured state and reflects light is filled in the surrounding of a chip-like light emitting body that is mounted on a substrate, and is thereafter cured, thereby forming a reflection member 15. Hereinafter, an explanation is made by regarding a side of a substrate 10 on which the light emitting body is mounted as an upper side. A top face of the reflection member 15 is an inclined surface with an edge 15a, on a side of the light emitting body, that is in contact with a lateral face of the light emitting body, and an edge 15b, on a side of an outer circumference, at least a part of which is located at a position higher than the height of a top face of the light emitting body. The inclined surface has a concave-shaped curved surface that is temporally inclined in a direction to approach the substrate 10 as being apart from the edge on the side of the light emitting body toward the side of the outer circumference, and is thereafter inclined in a direction to be apart from the substrate 10. This can obtain a light emitting device with high upward emission efficiency.

In the present embodiment, the light emitting body includes a light emitting element 11 including an LED chip, and a phosphor-containing layer 24 disposed on a top face of the light emitting element 11. The top face of the reflection member 15 preferably has the edge 15a, on the side of the light emitting element 11, that is in contact with a lateral face of the phosphor-containing layer 24, and the edge, on the side of the outer circumference, at least a part of which is higher than the height of the phosphor-containing layer 24.

A frame 16 stands at a position separated from a lateral face of the light emitting body in the surrounding of the light emitting body on the substrate 10, and the edge 15b of the top face of the reflection member 15 on the side of the outer circumference is desirably in contact with the frame 16.

An opening 16a is desirably formed in at least a part of the frame 16.

The edge 15a of the top face of the reflection member 15 on the side of the phosphor-containing layer 24 is desirably in contact with the lateral face of the phosphor-containing layer 24 below an upper end of the phosphor-containing layer 24.

Moreover, the invention provides a manufacturing method of a light emitting device as follows. In other words, the manufacturing method of a light emitting device includes: a step of disposing the phosphor-containing layer 24 on the top face of the light emitting element 11 mounted on the substrate 10; a step of disposing the frame 16 at a position separated from the lateral face of the phosphor-containing layer 24, on the substrate 10; a step of pushing a plate-like elastic body against top faces of the phosphor-containing layer 24 and the frame 16 so as to be come into contact therewith, and filling, in a state where a lower face of the elastic body is pushed up by the phosphor-containing layer 24 and the frame 16, a reflection material having fluidity in an uncured state in surroundings of the light emitting element 11 and the phosphor-containing layer 24 so as to be along the lower face of the elastic body; and a step of curing the reflection material, and forming the reflection member 15.

The height of the frame 16 is desirably higher than the top face of the phosphor-containing layer 24, and the thickness of the elastic body is desirably larger than a difference between the height of the frame 16 and the height of the phosphor-containing layer 24. The lower face of the elastic body desirably has a property to repel the reflection material. By disposing a plate-like member on an elastic body, and pressing the plate-like member, the elastic body is desirably pushed against the frame 16 and the phosphor-containing layer 24. The reflection material is desirably injected from the opening 16a included in the frame 16. Moreover, the manufacturing method of a light emitting device may include a step of removing the frame 16.

Hereinafter, specific embodiments will be described.

### First Embodiment

The light emitting element 11 including an LED chip of a flip-chip type is mounted on the sub-mount substrate 10 (hereinafter, referred to the substrate 10) with a top face on which wiring and electrodes are formed, and is bonded to and is mounted on electrodes 12 by soldering or bumping. The LED chip includes a laminated structure of a plurality of semiconductor material layers including a light-emitting layer, and electrodes.

The phosphor-containing layer 24 is disposed on the top face of the light emitting element 11. The phosphor-containing layer 24 is formed by materials in which phosphor particles are kneaded and dispersed to a resin or an inorganic binder. In the light emitting device in FIG. 1, the light emitting element 11 and the phosphor-containing layer 24 have the same size seen from the top faces, and lateral faces thereof are located at the identical position. Moreover, in the present embodiment, the plate-like phosphor-containing layer 24 with the flat top face is disposed on the top face of the light emitting element 11.

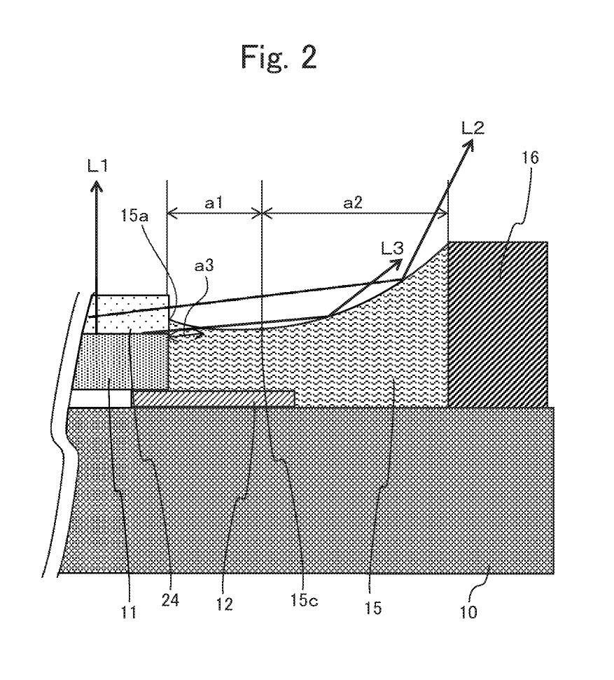

The surrounding of the light emitting element 11 is filled with the reflection member 15. The top face of the reflection member 15 is a curved inclined surface having a concave shape. More specifically, as illustrated in FIG. 2, the top face of the reflection member 15 is an inclined surface with the edge 15a, on the side of the light emitting element 11, that is in contact with the lateral face of the phosphor-containing layer 24, and the edge 15b, on the side of the outer circumference, at least a part of which is located at a position higher than the height of the phosphor-containing layer 24. The inclined surface of the reflection member 15 is a curved surface that is temporally inclined (region a1) in a direction to approach the substrate 10 as being apart from the edge on the side of the phosphor-containing layer 24 toward the side of the outer circumference, approaches closest to the substrate 10 in a lowermost part 15c, and is inclined (region a2) in a direction to be further apart from the substrate 10 on the side of the outer circumference.

The light emitting device with such a configuration allows the light emitting device with high emission efficiency of light that is emitted upward from the light emitting element 11 to be provided. It should be noted that optical paths of light that is emitted from the light emitting element 11 will be described later in details.

The lowermost part 15c is preferably positioned above an upper end of the light emitting element 11. In other words, a distance between the substrate 10 and the lowermost part 15c is preferably longer than a distance between the substrate 10 and the upper end of the light emitting element 11.

The frame 16 is disposed in an outside of the light emitting element 11. A space between the light emitting element 11 and the frame 16 is filled with the reflection member 15. The reflection member 15 is formed in such a manner that a reflection material 15A in an uncured state obtained by mixing particles having a light scattering property into a resin or a binder of inorganic materials is injected into a space between the light emitting element 11 and the frame 16, and cured.

The edge 15b is in contact with a portion of the frame 16 slightly below an upper end of the frame 16, but may be in contact with the upper end of the frame 16. Moreover, the edge 15a is in contact with the phosphor-containing layer 24 between the upper end and a lower end of the phosphor-containing layer 24.

The frame 16 stands from the substrate 10 so as to be higher than a height of the phosphor-containing layer 24 from the substrate 10 in order that at least a part of the edge 15b of the reflection member 15 on the side of the outer circumference is higher than the height of the phosphor-containing layer 24. In this example, the frame 16 stands along an outer circumferential edge of the substrate 10, and includes the opening 16a in a part of the frame 16. The arrangement of the frame 16 and the opening 16a is not limited to this example, but a plurality of separated frames 16 may be employed, for example. The opening 16a is formed so as to fill the reflection member 15, and thus may be formed in at least a part of the frame 16.

As the substrate 10, for example, a resin substrate may be used. As another example, a substrate made of AlN ceramic on which an Au wiring pattern or the like is formed may be used. As a bump, for example, an Au bump is used. The light emitting element 11 that emits light of a desired wavelength is prepared. For example, the light emitting element 11 that emits blue light is used.

As the phosphor of the phosphor-containing layer 24, a phosphor that emits fluorescence having a desired wavelength using light from the light emitting element 11 as excitation light is used. Specifically, for example, a phosphor (for example, YAG phosphor) that is excited by light emission of the light emitting element 11 that emits blue light, and emits yellow fluorescence is used. This can provide a light emitting device that emits white light in which the blue light and the yellow light are mixed. As the frame 16, a ceramic ring is used, for example.

As a binder of the reflection member 15, a thermal curable resin such as a silicone resin, an epoxy resin, or a fluorine resin, or a thermoplastic resin such as a plastic or nylon based resin can be used. As scatter materials (particles), a metal oxide such as a titanium oxide, a zinc oxide, or alumina can be used.

The higher concentration of the scatter particles of the reflection member 15 results in the higher reflection rate, which can desirably reduce evanescent light, however, the fluidity is lowered when the concentration becomes too high. Accordingly, the maximum concentration of the scatter particles that can maintain the fluidity for filling the reflection member 15 in the surrounding of the light emitting element 11 is desirably set.

Subsequently, with reference to FIG. 2, paths of light emitted from the light emitting element 11 will be described.

The entire lateral face of the light emitting element 11 is covered with the reflection member 15, light that is intended to be emitted from the lateral face of the light emitting element 11 is shielded. Light that is emitted upward from the light emitting element 11 enters the phosphor-containing layer 24 that is positioned upward.

Part of the light (for example, blue light) that is emitted from the light emitting element 11 and enters the phosphor-containing layer 24 is absorbed by a phosphor included in the phosphor-containing layer 24, and is converted into fluorescence (for example, yellow light). The light (blue light) that is not absorbed by the phosphor and the fluorescence (yellow light) are mixed to become mixed light (white light). The mixed light is emitted from the phosphor-containing layer 24.

Light L1 to be emitted from the top face of the phosphor-containing layer 24 is emitted upward without any change. In contrast, light L2 to be emitted from the lateral face of the phosphor-containing layer 24 in an inclined direction is reflected on the top face of the reflection member 15, and travels upward.

Moreover, light L3 to be emitted from a portion of the lateral face of the phosphor-containing layer 24 that is covered with the reflection member 15 enters the reflection member 15. The light L3 that passes through the reflection member 15 has a short path as illustrated by an arrow a3 because of the region a1 where the inclined surface of the reflection member 15 is inclined toward the side of the substrate 10 in the present application. Accordingly, the greater part of the light L3 can pass through the reflection member 15, and is reflected on the top face of the reflection member 15, and travels upward.

In this manner, the light emitting device can concentrate light above by causing not only the light L1 emitted upward from the phosphor-containing layer 24 but also the light L2 emitted from the lateral face of the phosphor-containing layer 24 to reflect on the top face of the reflection member 15. Accordingly, the light emitting device can improve the light intensity of light to be emitted upward.

In addition, as indicated by the light L3, the light emitting device can cause the light that is emitted from the portion of the phosphor-containing layer 24 covered with the reflection member 15 to pass through the reflection member 15 that covers the phosphor-containing layer 24, and emit upward. Accordingly, the light emitting device can prevent lateral light emitting of the phosphor-containing layer 24 from being entirely shielded by the reflection member 15, and thereby can improve the usage efficiency of light that is emitted from the light emitting element 11.

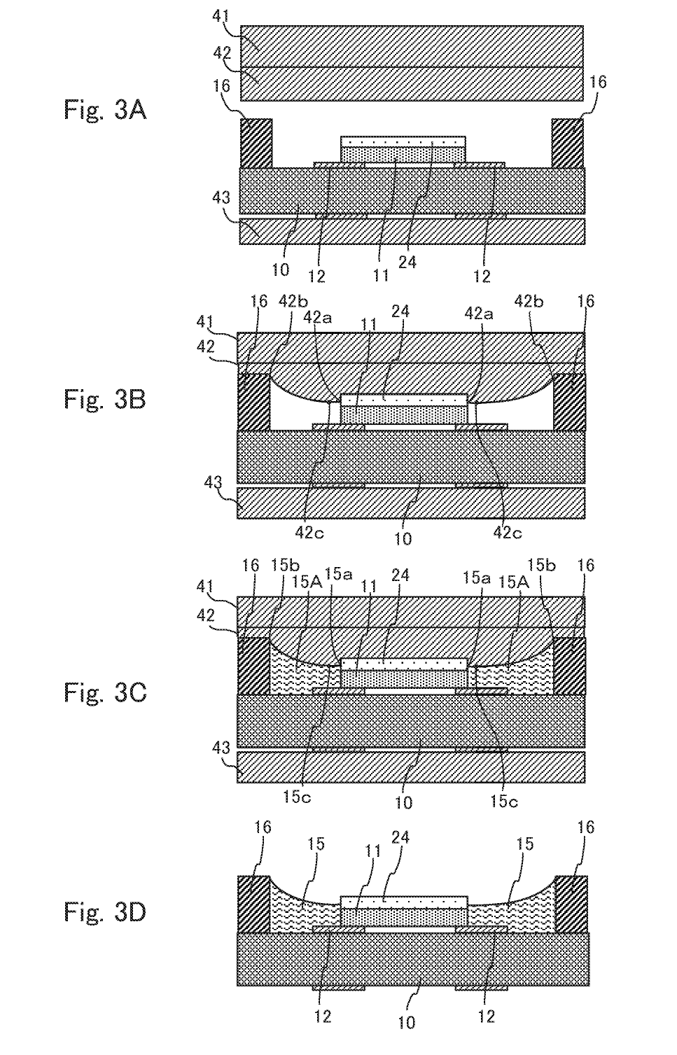

Next, a manufacturing method of the light emitting device according to the present embodiment will be described using FIGS. 3A to 3D. Firstly, as in FIG. 3A, an upper mold 41 serving as one example of a plate-like member, a mold releasing film 42 serving as one example of an elastic body that is stuck on the upper mold 41, and a lower mold 43 are prepared.

In this example, metallic molds with 0.42 mm squares are respectively used as the upper mold 41 and the lower mold 43. Moreover, a film having prescribed shape-following-up properties and mold release properties can be used as the mold releasing film 42. In this example, as the mold releasing film 42, Fluon® ETFE Film (trade name) (registered trademark) including fluorine resin, manufactured by ASAHI GLASS CO., LTD is used. The thickness of the mold releasing film 42 is preferably more than a difference between the height of the edge 15a of the top face of the reflection member 15 on the side of the phosphor-containing layer 24 and the height of the edge 15b thereof on the side of the outer circumference, and was set to 0.1 mm in this example. It should be noted that the modulus of elasticity of the mold releasing film 42 is 1000 MPa at the temperature of 25 degrees in this example. The scratching test in conformity with JISK5600-5-4 revealed that the hardness of the hardest pencil with which no scratch occurred was 5B.

The substrate 10 is disposed on the lower mold 43 such that a surface on which the light emitting element 11 and the like are disposed is on top. The substrate 10 with 0.43 mm squares was used in this example. Element electrodes of a flip-chip type and with 1 mm squares of the light emitting element 11 are bonded to and mounted on the electrodes 12 on the top face of the substrate 10 by soldering or bumping. The frame 16 is disposed and fixed to a position that is separated from the lateral face of the phosphor-containing layer 24, on the substrate 10. Next, the sheet-like phosphor-containing layer 24 with a thickness of 50 to 100 μm and 1 mm squares obtained by being phosphor particles kneaded with a binder and cured is prepared, and is mounted on the top face of the light emitting element 11. It should be noted that the phosphor-containing layer 24 may be formed in such a manner that the top face of the light emitting element 11 is coated with phosphor particles so as to have a prescribed thickness by printing or potting, and the phosphor particles are then cured under a prescribed condition.

Next, as in FIG. 3B, the upper mold 41 is moved to the side of the substrate 10, and the mold releasing film 42 is pushed against the top face of the phosphor-containing layer 24 and the top face of the frame 16 so as to be come into contact therewith, by the upper mold 41. This causes the center part of the mold releasing film 42 to be sandwiched between the upper mold 41 and the top face of the phosphor-containing layer 24, so that a lower face of the mold releasing film 42 is pushed up by the top face of the phosphor-containing layer 24. The mold releasing film 42 in the surrounding of the phosphor-containing layer 24 becomes a downward convex shape due to the elasticity thereof. Accordingly, the mold releasing film 42 comes into contact with not only the top face of the phosphor-containing layer 24 but also an upper portion of the lateral face of the phosphor-containing layer 24 to cover contacts 42a of the lateral face of the phosphor-containing layer 24. In other words, the upper portion of the phosphor-containing layer 24 is buried in the mold releasing film 42. This prevents the reflection member 15 from reaching above the contacts 42a, and a portion of the lateral face of the phosphor-containing layer 24 above the contacts 42a from being covered with the reflection member 15.

Moreover, the mold releasing film 42 is pushed against the top face of the frame 16 so as to come into contact therewith to sandwich end portions of the mold releasing film 42 between the upper mold 41 and the top face of the frame 16, so that the lower face of the mold releasing film 42 is pushed up by the top face of the frame 16. Accordingly, the mold releasing film 42 in the surrounding of the frame 16 becomes a downward convex shape due to the elasticity thereof, so that the mold releasing film 42 comes into contact with not only the top face of the frame 16 but also an upper portion of the lateral face of the frame 16 to cover contacts 42b of the lateral face of the frame 16. The frame 16 has a height higher than that of the phosphor-containing layer 24, so that end portions of the lower face of the mold releasing film 42 have a height higher than that of the center part of the lower face of the mold releasing film 42.

The lower face of the mold releasing film 42 from the contact 42a in contact with the lateral face of the phosphor-containing layer 24 to the contact 42b in contact with the lateral face of the frame 16 becomes a curved inclined surface in which the contact 42b has a height higher than that of the height of the phosphor-containing layer 24. More specifically, the inclined surface of the mold releasing film 42 becomes a curved surface that is temporarily inclined in a direction to approach the substrate 10 as being apart from the contact 42a toward the contact 42b, approaches closest to the substrate 10 in a lowermost part 42c, and is inclined in a direction to be further apart from the substrate 10. In this example, the distance from the contact 42a to the lowermost part 42c was about 0.03 mm.

Next, the reflection material 15A obtained by kneading scatter particles with a binder and having fluidity in an uncured state is prepared. After the reflection material 15A is filled in a space between the phosphor-containing layer 24 and the frame 16 from the opening 16a of the frame 16 illustrated in FIG. 1A until the reflection material 15A is in contact with the mold releasing film 42 as in FIG. 3C, the uncured reflection material 15A is primarily cured under the prescribed condition such as heating. This causes the reflection material 15A to be cured to the extent that the shape thereof is maintained.

The top face of the reflection material 15A becomes an inclined surface along the curved surface included in the lower face of the mold releasing film 42. In other words, the top face of the reflection material 15A becomes an inclined surface with the edge 15a, on the side of the light emitting element 11, that is in contact with the lateral face of the phosphor-containing layer 24, and the edge 15b, on the side of the outer circumference, at least a part of which is located at a position higher than the height of the phosphor-containing layer 24. The inclined surface of the reflection material 15A is a curved surface that is temporally inclined in a direction to approach the substrate 10 as being apart from the edge on the side of the phosphor-containing layer 24 toward the side of the outer circumference, approaches closest to the substrate 10 in the lowermost part 15c, and is inclined in a direction to be apart from the substrate 10. The edge 15a, the edge 15b and the lowermost part 15c in FIG. 3C respectively are in contact with the contact 42a, the contact 42b, and the lowermost part 42c in FIG. 3B.

Next, as in FIG. 3D, the substrate 10 is taken out from between the upper mold 41 and the lower mold 43. The mold releasing film 42 having mold release properties can repel the reflection material 15A and separate from the reflection material 15A in a state where the reflection material 15A is not entirely cured, while maintaining the shape of the reflection material 15A. The reflection material 15A is then secondarily cured under the prescribed condition such as heating to form the reflection member 15 while maintaining the shape of the reflection material 15A described above. As in the foregoing, the light emitting device according to the present embodiment is manufactured.

As described the above, manufacturing the compact light emitting device using the mold releasing film 42 eliminates the necessity of producing a metallic mold for each size of the light emitting element 11. This eliminates the necessity of preparing a metallic mold in advance, and can reduce the cost. In addition to this, the difficulty for processing the compact metallic mold is resolved.

Adjusting the thicknesses of the light emitting element 11 and the phosphor-containing layer 24, the height of the frame 16, the thickness of the mold releasing film 42, the elastic force of the mold releasing film 42, and the like can easily change the heights of the edges 15a and 15b and the lowermost part 15c, and the curvature radius of the curved surface included in the top face of the reflection member 15.

The edge 15b becomes higher than the edge 15a in the reflection member 15, so that the curvature radius of the curved surface formed by the top face of the reflection member 15 is smaller than the curvature radius of a concave-shaped meniscus when the uncured reflection material 15A is dropped between the light emitting element 11 and the frame 16.

Moreover, the reflection material 15A is filled in a state where the mold releasing film 42 is pushed against the top face of the phosphor-containing layer 24 and the top face of the frame 16, so that the reflection material 15A does not spread over the top face of the phosphor-containing layer 24 and the top face of the frame 16. Accordingly, the amount of filling of the reflection material 15A is not required to be controlled so as to prevent the reflection material 15A from spreading over the top face of the phosphor-containing layer 24.

In addition, the reflection member 15 is filled as the uncured reflection material 15A, and thus can be formed to be close to the light emitting element 11, so that the light emitting device having a small light emitting area can be provided.

### Second Embodiment

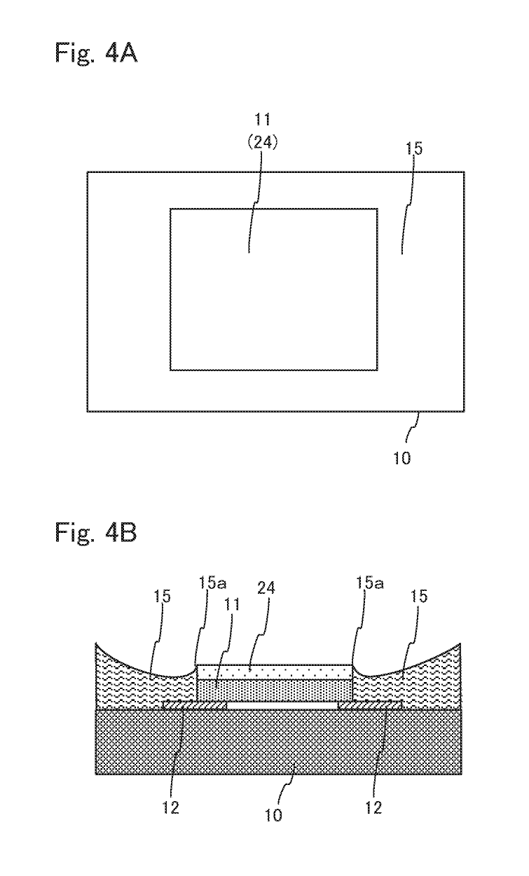

Alight emitting device according to a second embodiment will be described using FIGS. 4A and 4B. This light emitting device is different from that in the first embodiment in that no frame 16 in the first embodiment is provided. Moreover, the edge 15a of the top face of the reflection member 15 on the side of the phosphor-containing layer 24 is in contact with an upper end of the lateral face of the phosphor-containing layer 24. The other configurations are similar to those of the light emitting device in the first embodiment, and the light emitting element 11 is bonded to and mounted on the electrodes 12 on the substrate 10 by soldering or bumping, on the substrate 10. The phosphor-containing layer 24 is disposed on the top face of the light emitting element 11. The surroundings of the light emitting element 11 and the phosphor-containing layer 24 are filled with the reflection member 15.

It should be noted that the light emitting device according to the present embodiment can be manufactured by the manufacturing method having been described in the first embodiment in such a manner that after the reflection member 15 is primarily cured or secondarily cured, the frame 16 is removed with the substrate 10 by being cut by dicing, for example.

Moreover, in order to bring the edge 15a of the reflection member 15 into contact with the upper end of the lateral face of the phosphor-containing layer 24, the mold releasing film 42 having the elastic force larger than that used in the first embodiment may be used, or a method of weakening the force of the mold releasing film 42 to push the top face of the phosphor-containing layer 24 and the top face of the frame 16 may be employed. As for the other processes in the manufacturing method, the same processes in the manufacturing method of a light emitting device in the first embodiment may be used.

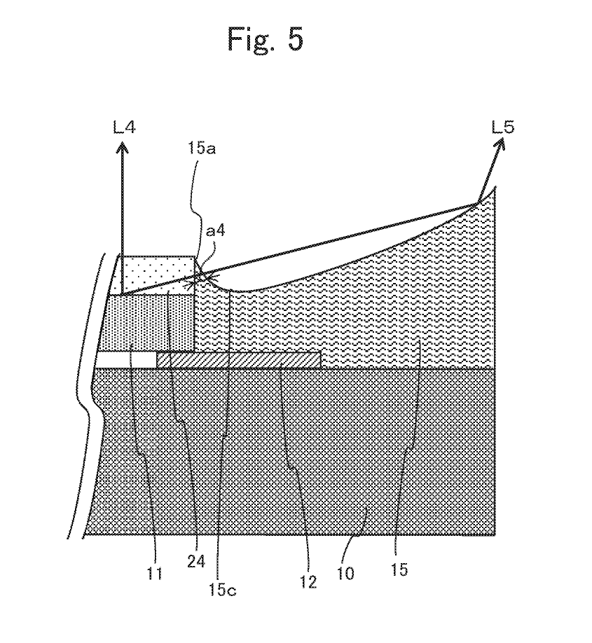

Subsequently, with reference to FIG. 5, paths of light emitted from the light emitting element 11 in the second embodiment will be described.

The entire lateral face of the light emitting element 11 is covered with the reflection member 15, thereby light to be emitted from the lateral face of the light emitting element 11 is shielded. Light to be emitted upward from the light emitting element 11 enters the phosphor-containing layer 24. Light L4 to be emitted from the top face of the phosphor-containing layer 24 is emitted upward without any change.

Light L5 to be emitted from the lateral face of the phosphor-containing layer 24 passes through the reflection member 15, is reflected on the top face of the reflection member 15, and travels upward, similar to the light L3 in the first embodiment.

In this manner, the light emitting device in the second embodiment not only can cause the light L4 to emit upward from the top face of the phosphor-containing layer 24, but also can cause the light L5 emitted from the lateral face of the phosphor-containing layer 24 to reflect on the top face of the reflection member 15 and thereby to emit upward. Accordingly, it is possible to improve the light intensity. Therefore, it is possible to improve the usage efficiency of light that is emitted from the light emitting element 11.

The phosphor-containing layer 24 to be mounted on the light emitting element 11 may have a size larger than that of the top face of the light emitting element 11. The sizes of the substrate 10, the light emitting element 11, and the phosphor-containing layer 24, the thickness of the mold releasing film 42, and the like are not limited to those in the examples described above, but various sizes can be employed.

It should be noted that a transparent material layer that is transparent with respect to the light emitted by the light emitting element 11 and the fluorescence emitted by the phosphor-containing layer 24 may be mounted on the phosphor-containing layer 24, and a plate-like transparent member may be mounted on the transparent material layer. In addition to this, a plate member and other members in accordance with a desired configuration may be mounted.

The explanation has been made that the light emitting device in the abovementioned embodiments performs wavelength conversion of part of light emitted by the light emitting element 11 by the phosphor-containing layer 24, and releases light in which light emission by the light emitting element 11 and light emission by the phosphor are mixed. However, the light emitting device may be provided with no phosphor-containing layer 24 when the wavelength conversion by the phosphor is not performed. Moreover, a configuration in which a transparent protective layer that includes no phosphor and is transparent with respect to light emitted by the light emitting element 11 is formed, instead of the phosphor-containing layer 24, may be employed.

When the configuration in which no phosphor-containing layer 24 is provided is employed, the light emitting element 11 serves as a light emitting body. When the configuration in which no phosphor-containing layer 24 is provided is employed, the top face of the reflection member 15 becomes an inclined surface with the edge 15a, on the side of the light emitting element, that is in contact with the lateral face of the light emitting element 11, and the edge 15b, on the side of the outer circumference, at least a part of which is located at a position higher than the height of the top face of the light emitting element 11. The inclined surface has a concave-shaped curved surface that is temporally inclined in a direction to approach the substrate 10 as being apart from the edge 15a on the side of the light emitting element 11 toward the side of the outer circumference, and is thereafter inclined in a direction to be apart from the substrate 10. A part of the upper lateral face of the light emitting element 11 is exposed from the reflection member 15. It should be noted that the edge 15a of the reflection member 15 is preferably positioned above a light-emitting layer in the light emitting element 11.

Such a configuration allows a light emitting device with high upward emission efficiency of light emitted from the light-emitting layer in the light emitting element 11 to be obtained.

A manufacturing method of a light emitting device having the configuration in which no phosphor-containing layer 24 is provided may merely omit the process of disposing the phosphor-containing layer 24 after the light emitting element 11 is mounted on the substrate 10, and fill, in a state where the mold releasing film 42 is pushed against the top face of the light emitting element 11 and the top face of the frame 16 so as to be come into contact therewith, the reflection material 15A having fluidity in an uncured state in the surrounding of the light emitting element 11 so as to be along the lower face of the mold releasing film 42, in the manufacturing method of a light emitting device in the first embodiment.

When a configuration in which a transparent protective layer that includes no phosphor and is transparent with respect to light emitted by the light emitting element 11 is disposed, instead of the phosphor-containing layer 24, is employed, the light emitting body includes the light emitting element 11 and the transparent protective layer. When a configuration in which a transparent protective layer that includes no phosphor and is transparent with respect to light emitted by the light emitting element 11 is disposed, instead of the phosphor-containing layer 24, is employed, the top face of the reflection member 15 becomes an inclined surface with the edge 15a, on the side of the light emitting element, that is in contact with the lateral face of the transparent protective layer, and the edge 15b, on the side of the outer circumference, at least a part of which is located at a position higher than the height of the top face of the transparent protective layer. The inclined surface has a concave-shaped curved surface that is temporally inclined in a direction to approach the substrate 10 as being apart from the edge 15a on the side of the light emitting element 11 toward the side of the outer circumference, and is thereafter inclined in a direction to be apart from the substrate 10. A part of the upper lateral face of the transparent protective layer is exposed from the reflection member 15.

Such a configuration allows a light emitting device with high upward emission efficiency of light emitted from the light emitting element 11 to be obtained.

A manufacturing method of a light emitting device having the configuration in which a transparent protective layer that includes no phosphor and is transparent with respect to light emitted by the light emitting element 11 is disposed, instead of the phosphor-containing layer 24, is preferably as follows: after the light emitting element 11 is mounted on the substrate 10, a transparent protective layer is disposed on the top face of the light emitting element 11; and in a state where the mold releasing film 42 is pushed against the top face of the transparent protective layer and the top face of the frame 16 so as to come into contact therewith, the reflection material 15A having fluidity in an uncured state is filled in the surroundings of the light emitting element 11 and the transparent protective layer so as to be along the lower face of the mold releasing film 42.

### REFERENCE SIGNS LIST

10 . . . sub-mountsubstrate (substrate), 11 . . . light emitting element, 12 . . . electrode, 15 . . . reflection member, 16 . . . frame, 24 . . . phosphor-containing layer

What is claimed is:

1. A light emitting device comprising:
a substrate; a chip-like light emitting body that is mounted on the substrate; and a reflection member that is filled in a surrounding of the light emitting body, wherein
a top face of the reflection member is an inclined surface with an edge, on a side of the light emitting body, that is in contact with a lateral face of the light emitting body, and an edge, on a side of an outer circumference, at least a part of which is located at a position higher than a height of the light emitting body, and
the inclined surface has a concave-shaped curved surface that is temporarily inclined in a direction to approach the substrate as being apart from the edge on the side of the light emitting body toward the side of the outer circumference, and is thereafter inclined in a direction to be apart from the substrate.

2. The light emitting device according to claim 1, wherein the light emitting body includes a light emitting element, and a phosphor-containing layer that is disposed on a top face of the light emitting element, and the top face of the reflection member includes the edge, on a side of the light emitting element, that is in contact with a lateral face of the phosphor-containing layer, and the edge, on the side of the outer circumference, at least a part of which is higher than a height of the phosphor-containing layer.

3. The light emitting device according to claim 2, wherein the edge of the top face of the reflection member on a side of the phosphor-containing layer is in contact with the lateral face of the phosphor-containing layer below an upper end of the phosphor-containing layer.

4. The light emitting device according to claim 1, wherein the light emitting body includes the light emitting element, and a transparent protective layer that is disposed on the top face of the light emitting element, and the top face of the reflection member includes the edge, on a side of the light emitting element, that is in contact with a lateral face of the transparent protective layer, and the edge, on the side of the outer circumference, at least a part of which is higher than a height of the transparent protective layer.

5. The light emitting device according to claim 1, wherein a frame stands at a position separated from the lateral face of the light emitting body in the surrounding of the light emitting body on the substrate, and the edge of the top face of the reflection member on the side of the outer circumference is in contact with the frame.

6. The light emitting device according to claim 5, wherein an opening is formed in at least a part of the frame.

7. A manufacturing method of a light emitting device comprising:
a step of disposing a phosphor-containing layer on a top face of a light emitting element that is mounted on a substrate;
a step of disposing a frame at a position separated from a lateral face of the phosphor-containing layer, on the substrate;
a step of pushing a plate-like elastic body against top faces of the phosphor-containing layer and the frame so as to come into contact therewith, and filling, in a state where a lower face of the elastic body is pushed up by the phosphor-containing layer and the frame, a reflection material having fluidity in an uncured state in surroundings of the light emitting element and the phosphor-containing layer so as to be along the lower face of the elastic body; and
a step of curing the reflection material to form a reflection member.

8. The manufacturing method of a light emitting device according to claim 7, wherein a height of the frame is higher than that of the top face of the phosphor-containing layer, and a thickness of the elastic body is larger than a difference between the height of the frame and a height of the phosphor-containing layer.

9. The manufacturing method of a light emitting device according to claim 7, wherein a top face of the reflection member is an inclined surface with an edge, on a side of the light emitting element, that is in contact with a lateral face of the phosphor-containing layer, and an edge, on a side of an outer circumference, at least a part of which is located at a position higher than the height of the phosphor-containing layer.

10. The manufacturing method of a light emitting device according to claim 7, wherein a plate-like member is disposed on the elastic body, and the plate-like member is pressed to push the elastic body against the frame and the phosphor-containing layer.

11. A manufacturing method of a light emitting device comprising:
a step of mounting a light emitting element on a substrate;
a step of disposing a frame at a position separated from a lateral face of the light emitting element, on the substrate;
a step of pushing a plate-like elastic body against top faces of the light emitting element and the frame so as to come into contact therewith, and filling, in a state where a lower face of the elastic body is pushed up by the light emitting element and the frame, a reflection material having fluidity in an uncured state in a surrounding of the light emitting element so as to be along the lower face of the elastic body; and
a step of curing the reflection material to form a reflection member.

12. A manufacturing method of a light emitting device comprising:
a step of disposing a transparent protective layer on a top face of a light emitting element that is mounted on a substrate;
a step of disposing a frame at a position separated from a lateral face of the transparent protective layer, on the substrate;
a step of pushing a plate-like elastic body against top faces of transparent protective layer and the frame so as to come into contact therewith, and filling, in a state where a lower face of the elastic body is pushed up by transparent protective layer and the frame, a reflection material having fluidity in an uncured state in surroundings of the light emitting element and the transparent protective layer so as to be along the lower face of the elastic body; and
a step of curing the reflection material to form a reflection member.
